(19) United States
(12) Patent Application Publication
(10) Pub. No.: US 2007/0019385 A1
(43) Pub. Date: Jan. 25, 2007

(54) Heat-dissipating device

(76) Inventor: Chun-Hou Chan, Hsi Chih City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/186,988

(22) Filed: Jul. 22, 2005

(51) Int. Cl. H05K 7/20

(52) U.S. Cl. 361/704

(57) ABSTRACT

A heat-dissipating device suited for use with a liquid heat-transfer medium is proposed. It has a heat sink and an isolation layer. The isolation layer is disposed on a surface of the heat sink in contacts with the liquid heat-transfer medium. The isolation layer surrounds the liquid heat-transfer medium to prevent it from leaking.

### BACKGROUND OF THE INVENTION

1. Field of the Invention

The present invention is related to a heat-dissipating device suited for use with a liquid heat-transfer medium, and more particularly, to a heat-dissipating device that can prevent the liquid heat-transfer medium from leaking.

2. Description of Related Art

With the rapid progress of computer industries, electronic heat sources, such as chips or central processing units (CPUs), have faster and faster processing speeds and produce more and more heat. In order to dissipate heat and maintain a normal operation state, a heat-dissipating device is usually attached to the electronic heat source. The heat-dissipating device has a larger heat-dissipating surface. The heat-dissipating device uses its heat-dissipating fins to dissipate heat.

An example of a conventional heat-dissipating device is disclosed in TW Patent No. 562395 issued on Nov. 11, 2003. In order to pass heat produced by the heat source to a heat-dissipating device, a thermal grease is applied between the heat source and the heat-dissipating device. Via the thermal grease, heat can be passed from the heat source to the heat-dissipating device and then be dissipated.

As described above, the thermal grease serves as a heat-transfer medium. However, the heat transfer coefficient of the thermal grease is very small, so the thermal grease is inefficient in heat transfer. Hence, heat generated by chips or CPUs usually cannot be effectively passed to the heat-dissipating device, resulting in a low overall heat dissipation efficiency.

For resolving this problem, an alloy with a low melting point is used to attach the heat-dissipating device to a heat source, and serves as a heat-transfer medium. Since the heat transfer coefficient of the alloy is higher, heat generated by the heat source can be effectively passed to the heat-dissipating device. Hence, the overall heat dissipation efficiency is higher.

However, the low-melting-point alloy mentioned above is disposed between the heat source and the heat-dissipating device. Once the temperature of the heat source is higher than the melting point of the alloy, the alloy melts and becomes a liquid. In this situation, the alloy may flow out from the original position and the heat dissipation efficiency is degraded.

### SUMMARY OF THE INVENTION

An objective of the present invention is to provide a heat-dissipating device suited for use with a liquid heat-transfer medium. In the present invention, an isolation layer is disposed on a surface of a heat sink in contact with the liquid heat-transfer medium. The isolation layer surrounds the liquid heat-transfer medium. By using the isolation layer, the liquid heat-transfer medium is prevented from leaking. Hence, the heat transfer efficiency is kept high.

For achieving the above objective, the present invention provides a heat-dissipating device. It includes a heat sink and an isolation layer. The isolation layer is disposed on the heat sink and surrounds the liquid heat-transfer medium.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is an elevation view of a heat-dissipating device in accordance with the first embodiment of the present invention;

FIG. 2 is a cross-sectional view of the heat-dissipating device in accordance with the first embodiment of the present invention;

FIG. 3 is a cross-sectional view of the heat-dissipating device of the first embodiment of the present invention when in use;

FIG. 4 is a cross-sectional view of a heat-dissipating device in accordance with the second embodiment of the present invention;

FIG. 5 is an elevation of a heat-dissipating device in accordance with the third embodiment of the present invention; and

FIG. 6 is a cross-sectional view of the heat-dissipating device in accordance with the third embodiment of the present invention.

### DETAILED DESCRIPTION OF PREFERRED EMBODIMENTS

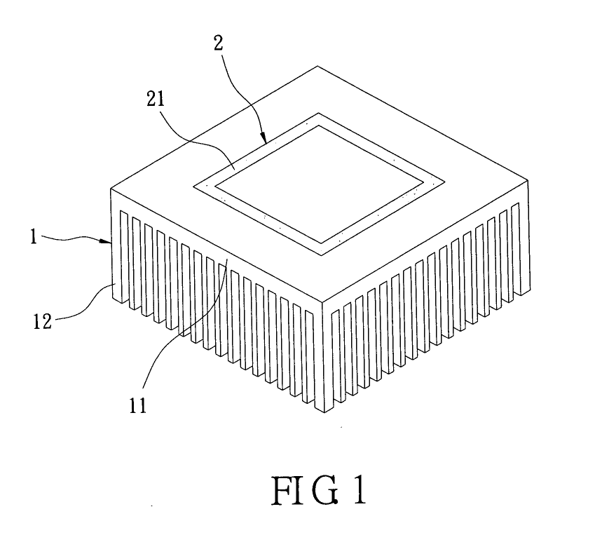

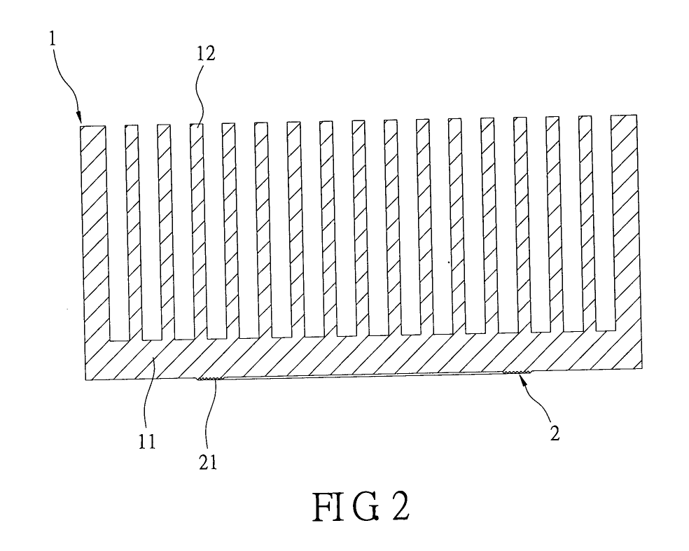

Reference is made to FIGS. 1-2. The present invention provides a heat-dissipating device suited for use with a liquid heat-transfer medium. It includes a heat sink 1 and an isolation layer 2. The heat sink 1 is made of copper or aluminum, which has a good heat-transfer property. The shape or structure of the heat sink 1 is not limited. The heat sink 1 can be any type of heat sinks. In this embodiment, the heat sink 1 has a base 11 and multiple fins 12. The fins 12 project from the base 11 and are formed on the base 11 as integral parts. In practice, the fins 12 can also be formed as separate components, and are attached to the base 11 when in use.

The isolation layer 2 is disposed on a surface of the base 11 of the heat sink 1. The isolation layer 2 can be provided via a post-processing step or formed when the heat sink 1 is made. In this embodiment, the isolation layer 2 is provided on the heat sink 1 via a post-processing step. In other words, the isolation layer 2 is provided on a surface of the base 11 of the heat sink 1 by using a sander. The shape of the isolation layer 2 can be rectangular or circular. By using the sander, the isolation layer 2 has a coarse surface 21, which can be used to prevent the liquid heat-transfer medium from leaking. The average roughness (Ra) of the coarse surface 21 is about 2-3 μm and the maximum height is about 20 μm in this embodiment. However, the present invention is not limited thereto. The combination mentioned above forms the heat sink of the present invention suited for use with a liquid heat-transfer medium.

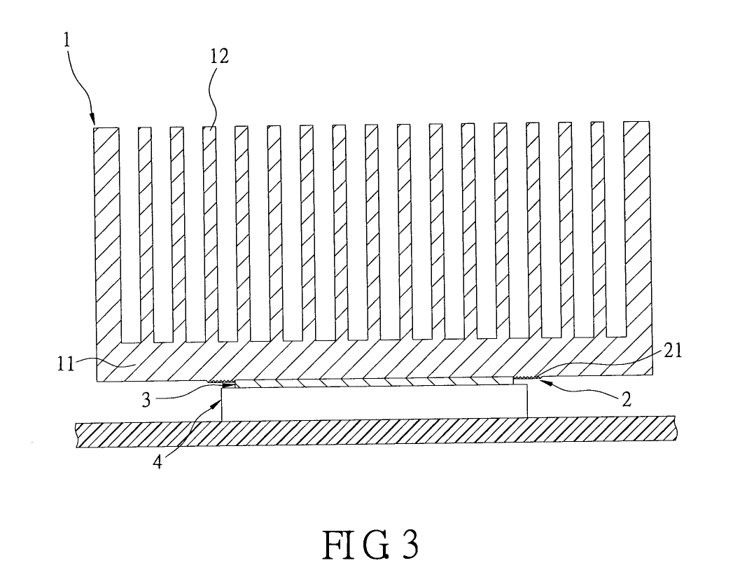

Reference is made to FIG. 3. An alloy 3 with a low melting point is provided on the base 11 of the heat sink 11 and surrounded by the isolation layer 2. The alloy 3 serves as a liquid heat-transfer medium and is in contact with a heat source 4, such as a chip or a CPU. By using the alloy 3, heat generated by the heat source 4 can be effectively passed to the heat sink 1. Hence, the heat-dissipation efficiency is high.

When the temperature of the heat source 4 is higher than the melting point of the alloy 3, the alloy 3 becomes a liquid heat-transfer medium. Due to the isolation layer 2, the liquid heat-transfer medium can be prevented from leaking.

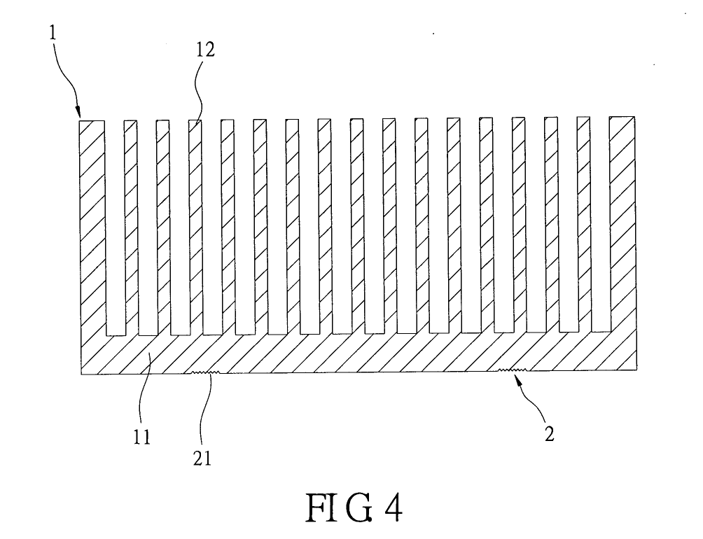

Reference is made to FIG. 4. In this embodiment, the isolation layer 2 is provided via a post-processing step. A chemical etching process is performed on a surface of the base 11 of the heat sink 1 to form the isolation layer 2. Via the chemical etching process, the isolation layer 2 has a coarse surface 21, which can prevent the liquid heat-transfer medium from leaking.

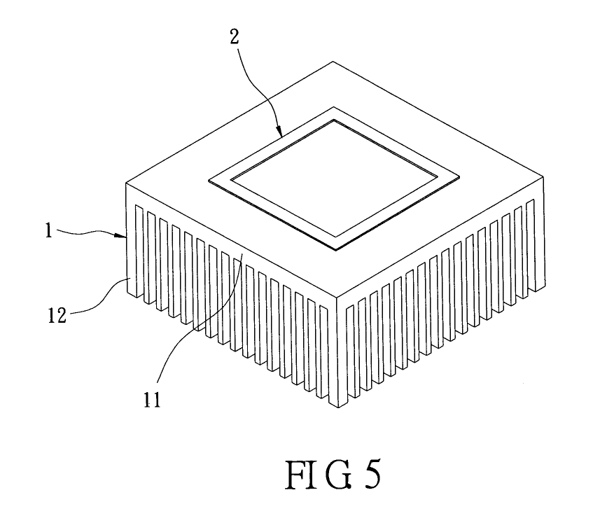

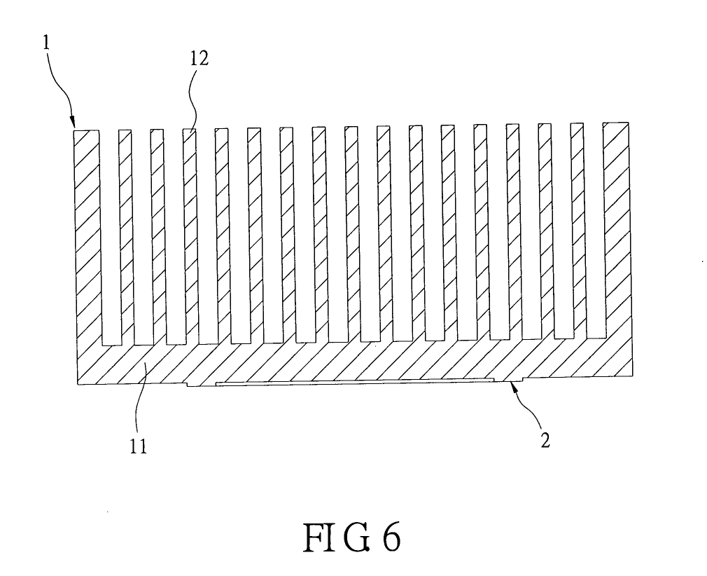

Reference is made to FIGS. 5-6. In this embodiment, the isolation layer 2 is formed on the heat sink 1 as an integral part. The isolation layer 2 can be a concave portion or a projecting portion formed on a surface of the base 11 of the heat sink 1. The isolation layer 2 has a height of about 0.5 mm and is used to prevent the liquid heat-transfer medium from leaking.

Summing up, the present invention disposes an isolation layer 2 on a surface of the heat sink 1 in contact with a liquid heat-transfer medium, i.e. the low-melting-point alloy 3. The isolation layer 2 surrounds the liquid heat-transfer medium to prevent the liquid heat-transfer medium from leaking. In this way, the present invention can keep a high heat-transfer efficiency.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A heat-dissipating device suited for use with a liquid heat-transfer medium, comprising:
a heat sink; and
an isolation layer disposed on the heat sink and surrounding the liquid heat-transfer medium.

2. The heat-dissipating device as claimed in claim 1, wherein the heat sink has a base and multiple fins projecting from the base, and the isolation layer is disposed on a surface of the base of the heat sink.

3. The heat-dissipating device as claimed in claim 1, wherein the isolation layer is disposed on the heat sink via a sander.

4. The heat-dissipating device as claimed in claim 1, wherein the isolation layer is disposed on the heat sink via a chemical etching process.

5. The heat-dissipating device as claimed in claim 1, wherein the isolation layer is disposed on the heat sink as an integral part thereof.

6. The heat-dissipating device as claimed in claim 1, wherein the isolation layer is a concave portion or a projecting portion disposed on the heat sink.

7. The heat-dissipating device as claimed in claim 1, wherein the isolation layer has a coarse surface.
